(19) United States
(12) Patent Application Publication
(10) Pub. No.: US 2015/0075595 A1
(43) Pub. Date: Mar. 19, 2015

(54) METHOD FOR PRODUCING A PHOTOVOLTAIC CELL WITH INTERDIGITATED CONTACTS IN THE BACK FACE

(71) Applicant: Commissariat à I'Energie Atomique et aux Energies Alternatives, Paris (FR)

(72) Inventor: Samuel Gall, Arradon (FR)

(73) Assignee: Commissariat à I'Energie Atomique et aux Energies Alternatives, Paris (FR)

(21) Appl. No.: 14/390,115

(22) PCT Filed: Apr. 3, 2013
(86) PCT No.: PCT/EP2013/057031

§ 371 Date: Oct. 2, 2014

(30) Foreign Application Priority Data
Apr. 3, 2012 (FR) 1253058

(51) Int. Cl. H01L 31/065; H01L 31/0224; H01L 31/18; H01L 31/0352

(52) U.S. Cl. CPC H01L 31/065; H01L 31/03529; H01L 31/022441; H01L 31/1864; H01L 31/1804
USPC 136/255; 438/87

(57) ABSTRACT

A method for producing a photovoltaic cell with interdigitated contacts in the rear face, comprising: providing a doped silicon substrate; forming, on the rear face of said substrate, a doped semiconductor layer with a first dopant species; forming, on said layer, a dopant layer comprising a second dopant species, of an electric type opposite to that of the first species; forming, in the doped layer, at least one doped region of a type opposite to that of the first species, by irradiation of at least one region of the dopant layer with a luminous flux of fluence greater than a threshold above which the dopants of the irradiated region of the dopant layer diffuse into the region underlying the doped layer in such a way as to exceed the concentration of the first dopant species; and forming, in the doped layer, at least one electrically insulating region, by selective irradiation of at least one region of the dopant layer with a luminous flux of which the fluence is in a range lower than said threshold, at which the dopants of the irradiated region of the dopant layer diffuse into the region underlying the doped semiconductor layer in such a way as to balance the concentrations of the two dopant species in said region.

### FIELD OF THE INVENTION

The present invention concerns a method for producing a photovoltaic cell with interdigitated contacts on the back surface.

### BACKGROUND OF THE INVENTION

Photovoltaic cells with interdigitated contacts on the back surface known as “Interdigitated Back Contact” (IBC) are promising cells on account of the high yield they produce.

Such cells comprise a doped silicon substrate coated on its front surface (i.e. the surface exposed to sun radiation) with a doped semiconductor layer of the same electric type as that of the substrate to form a “Front Surface Field” (FSF) to repel the charge carriers away from the surface.

On the back surface the substrate is coated with a semiconductor layer having a doped region of opposite electric type to that of the substrate to form the emitting region and ensure collection of the photocarriers generated by illumination of the cell, and with a doped region of same electric type as the substrate to form a repulsive “Back Surface Field” (BSF).

These two regions of the back surface are generally in the form of two interdigitated combs.

Passivation layers are formed on the front and back surfaces of the cell.

In addition, metal contacts are formed on each of the two regions of the back surface to ensure charge collection.

Said structures give high performance in terms of yield due to the absence of shadowing on the front surface (the contact metal lines being located solely on the back surface) and to reduced recombination on the front surface through the presence of the region providing the repulsive field FSF.

The manufacturer Sunpower has demonstrated that the yield obtained with such cells could reach 25%.

On the other hand, the manufacture of such cells is complex and costly since it requires numerous steps.

FIG. 1 illustrates an example of a photovoltaic cell of IBC type.

This cell has a silicon substrate 1 which in this example is of n type.

The substrate 1 is coated on its front surface F with an n+ doped semiconductor layer 2 forming the repulsive FSF field.

Preferably, said layer 2 is formed by high temperature diffusion of POCl₃ on the surface of the silicon substrate 1.

The layer 2 is then coated with a passivation layer 3, which also has anti-reflective properties, containing silicon nitride (SiNO.

Said layer is deposited for example by plasma enhanced chemical vapour deposit (PECVD).

On the back surface of B of the substrate 1, a p+ region 4 forming the emitter is formed by high temperature diffusion of BBr₃ in the silicon substrate 1 following a comb pattern.

Also an n+ region 5 is formed by high temperature diffusion of POCl₃ in the silicon substrate 1 following a comb pattern matching the pattern of region 4.

A stack of silicon oxide and nitride layers (SiO₂/SiNₓ), schematically illustrated in the form of a layer 6 is then deposited on the entire back surface to ensure passivation of the doped regions.

Metal lines 7, 8 are screen printed on the back surface with Ag serigraphy paste on the n+ regions and Ag/Al paste on the p+ regions.

According to one embodiment, the fabrication of the interdigitated p+ and n+ regions 4 and 5 requires the steps of depositing diffusion barriers, localised etching of said barriers using photolithography techniques followed by diffusion of BBr₃ and POCl₃ to form the p+ and n+ regions.

According to one embodiment, the fabrication of the interdigitated p+ and n+ regions 4 and 5 involves the steps of depositing doping layers containing either boron or phosphorus which are selectively removed before heating the substrate to cause diffusion of the dopant into the silicon substrate 1 and thereby form the p+ and n+ regions.

Additionally, the p+ and n+ regions must be electrically insulated from one another to prevent any risk of short circuiting.

This electrical insulation can be obtained by laser ablation or by preserving non-doped regions of the substrate between the n+ and p+ regions, at the cost of additional deposit and etching steps.

On account of the complexity of the fabrication of the n+ and p+ regions on the back surface, the price per kW obtained with these types of cells is high and scarcely competitive compared with the most widespread photovoltaic cells of homojunction type which give less good performance but are substantially less costly.

To increase the market share of IBC-type cells it would therefore be desirable to be able to fabricate the n+ and p+ regions on the back surface using a method that is less complex and less costly than existing methods.

It is therefore one objective of the invention to define a method for producing a photovoltaic cell with interdigitated back contacts which is simpler and cheaper than existing methods.

### BRIEF DESCRIPTION OF THE INVENTION

According to the invention there is proposed a method for producing a photovoltaic cell with interdigitated back contacts, comprising:
providing a doped silicon substrate;
forming on the back surface of said substrate a semiconductor layer doped with a first species of dopants;
forming on said doped semiconductor layer a so-called doping layer comprising a second species of dopants of opposite electric type to that of the first species;
forming in the doped semiconductor layer at least one doped region of opposite electric type to that of the first species by selective irradiation of at least one region of the doping layer via a luminous flux having fluence higher than a threshold called “doping inversion threshold” over and above which the dopants of the irradiated region of the doping layer diffuse into the underlying region of the doped semiconductor layer so as to exceed the concentration of the first species of dopants;
forming in the doped semiconductor layer at least one electrically insulating region via selective irradiation of at least one region of the doping layer via a luminous flux having fluence lying within a so-called “doping compensation range” that is lower than said doping inversion threshold and at which the dopants of the irradiated region of the doping layer diffuse into the underlying region of the doped semiconductor layer so as to obtain equilibrium concentrations of the two species of dopants in said region.

Said selective irradiation is advantageously performed on the back surface of the substrate.

The doped semiconductor layer can be formed by high temperature diffusion of a reagent containing the first dopant species via the back surface of the substrate.

The doping layer may be a layer of silicon nitride doped with the second species of dopants and deposited by plasma enhanced chemical vapour deposit (PECVD).

According to one embodiment of the invention, the first dopant species is of the same electrical type as the substrate.

For example, the substrate is n-doped and the first dopant species is phosphorus. The doped semiconductor layer may be formed by high temperature diffusion of POCl₃ via the back surface of the substrate.

The doping layer may then be a boron-doped layer of silicon nitride.

According to another embodiment, the first dopant species is of opposite electric type to the substrate.

For example the substrate is n-doped and the first dopant species is boron.

The doped semiconductor layer can be formed by high temperature diffusion of BBr₃ or de BCl₃ via the back surface of the substrate.

The doping layer may be a layer of phosphorus-doped silicon nitride.

Advantageously, the thickness of the doped semiconductor layer is between 100 nm and 1 μm and the thickness of the doping layer is between 10 and 300 nm.

Before forming the doping layer, advantageously a layer of silicon oxide is formed on the doped semiconductor layer.

Preferably, the selective irradiation(s) are performed using laser.

Also, the method further comprises the forming—on the front surface of said substrate—of a doped semiconductor layer of same electric type as the substrate, so as to form a repulsive electric field on said front surface.

Said repulsive electric field is preferably formed by high temperature diffusion of POCl₃ in the substrate.

A further subject of the invention concerns a structure comprising a doped silicon substrate successively coated with a semiconductor layer doped with a first dopant species and a so-called doping layer comprising a second dopant species of opposite electric type to the first species, characterized in that the doped semiconductor layer comprises at least one doped region of opposite type to the first species, comprising dopants of the second species in a higher concentration than the dopants of the first species, and an electrically insulating region comprising dopants of the second species in concentration equilibrium with the concentration of the dopants of the first species.

Finally, a further subject of the invention concerns a photovoltaic cell with interdigitated back contacts comprising a doped silicon substrate, and p+ and n+ doped regions on the back surface of said substrate in alternation and in the form of an interdigitated comb, said cell being characterized in that all said p+ and n+ regions have a substantially homogeneous concentration of dopants of one same species, and in that said cell further comprises, on the back surface of the substrate, a plurality of electrically insulating regions separating the p+ doped regions and the n+ doped regions, said electrically insulating regions having a concentration of dopants of said species that is substantially homogeneous with that of the p+ doped regions and n+ doped regions.

### BRIEF DESCRIPTION OF THE DRAWINGS

Other characteristics and advantages of the invention will become apparent from the following detailed description with reference to the appended drawings in which:

FIG. 1 illustrates the structure of a photovoltaic cell with interdigitated back contacts;

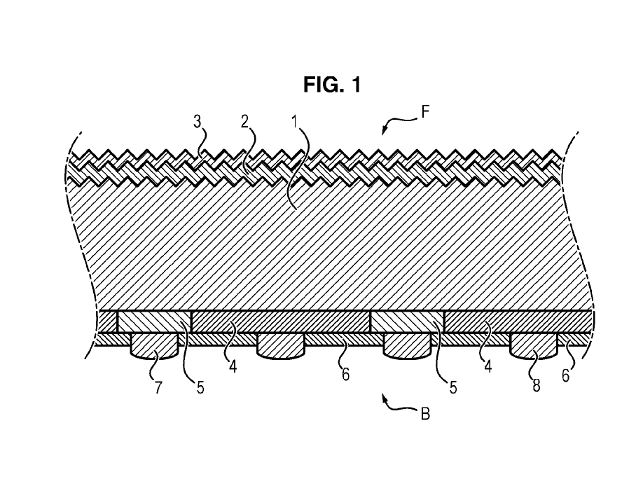

FIGS. 2A to 2C illustrate steps of the method according to one embodiment of the invention;

FIG. 3 shows the variation of the resistance Rsheet of a layer initially doped with boron as a function of the irradiation fluence by a laser source of a doping layer of SiN(P) deposited on said doped layer;

FIG. 4, for different irradiation fluence values, gives the concentration profiles of boron and phosphorus in said layer initially doped with boron;

FIG. 5 shows the variation of the resistance Rsheet of a layer initially doped with phosphorus as a function of the irradiation fluence by a laser source of a SiN(B) doping layer deposited on said doped layer;

FIG. 6, for different irradiation fluence values, shows the concentration profiles of boron and phosphorus in said layer initially doped with phosphorus;

FIGS. 7A to 7C illustrate the steps of an example of implementation of the invention.

### DETAILED DESCRIPTION OF THE INVENTION

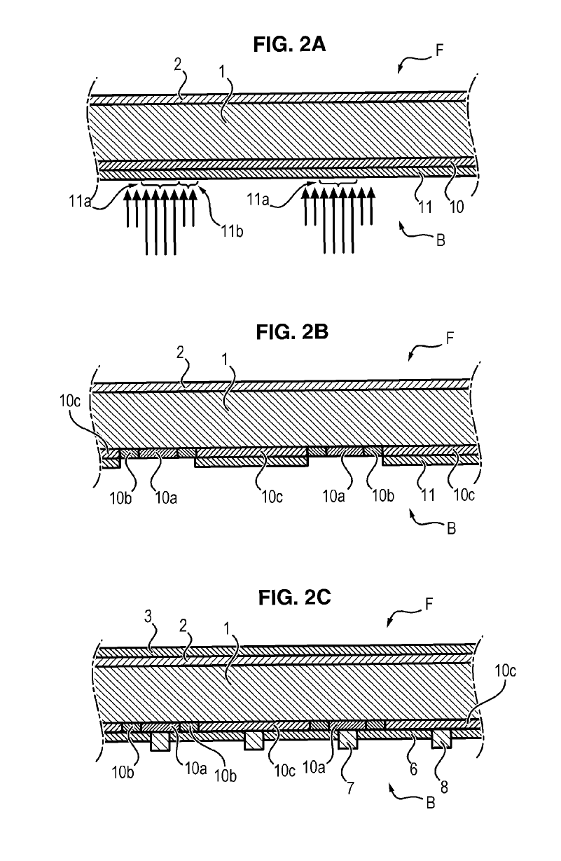

The steps of the method according to one embodiment of the invention are schematically illustrated in FIGS. 2A to 2C.

With reference to FIG. 2A, in a doped silicon substrate 1 there is formed the layer 2 forming the repulsive field FSF on the front surface and a doped layer 10 on the back surface.

In the example, the substrate is of n-type but as a variant it could be of p-type.

The doping of this substrate should advantageously allow obtaining good lifetimes (time between the creation of the electron/hole pairs and their recombination), typically higher than 700 μs, which corresponds to resistivity values of between 14 and 22 ohm.cm.

This substrate can be obtained using any known growth technique (e.g. of float zone type of by Czochralski process . . . ).

The layer 2 is doped with the same electric type as the substrate 1 but at a stronger doping level (n+ or n++).

The layer 2 preferably has RSheet type resistance (Sheet Resistance) in the order of 70 to 100 ohms-per-square.

In one particular embodiment of the invention, the layer 2 is formed in the substrate before the doped layer 10.

The forming of said FSF layer is known to the person skilled in the art and will therefore not be detailed herein.

For example, the layer 2 can be formed by high temperature diffusion of BCl₃ or BBr₃ via the front surface of the substrate 1.

Alternatively, it is also possible to perform phosphorus ion implantation through the front surface F of the substrate 1 followed by activation annealing.

A protective layer (not illustrated) is then deposited on the layer 2.

Said layer can be formed for example of a 200 nm layer of silicon dioxide deposited by PECVD at 450° C.

On the back surface B of the substrate there is then formed a semiconductor layer 10 doped with a first species of dopants.

According to a first embodiment of the invention, the dopants of this first species are of the same electric type as the substrate 1.

Advantageously the first dopant species is boron; the layer 10 is then p+-doped.

The doping level of said p+ layer is such that the Rsheet resistance is in the order of 50 and 100 ohms-per square.

According to a second embodiment of the invention, the dopants of this first species are of opposite type to the substrate 1.

The invention effectively allows great flexibility with regard to the choice of the first doping to be performed.

In this second case (described in detail in an example below) it is then possible simultaneously to form the layer 2 on the front surface and the doped layer 10 on the back surface of the substrate.

Advantageously the first dopant species is phosphorus; the layer 10 then has n+ doping.

The doped semiconductor layer 10 (and optionally the layer 2 if it is formed at the same step) is preferably formed by high temperature diffusion of a reagent containing the first dopant species via the back surface B of the substrate 1.

High temperature diffusion is a technique known per se and it is within the reach of the person skilled in the art to define the reagents and operating conditions to form the doped layer 10 whether of n+ or of p+ type.

Diffusion is conducted at high temperature, typically between 750° and 950°.

To form the p+ doped layer 10 in the substrate 1 of type n, boron is diffused at high temperature from BCl₃ or BBr₃ via the back surface B of the substrate, the front face being protected by the above-mentioned protective layer.

In general, to form the n+ doped layer 10 in the substrate 1 of n type, phosphorus is diffused at high temperature from POCl₃ via the back surface B of the substrate.

As indicated above, it is possible to form layer 2 and layer 10 in the same step if they are of the same electric type.

In the high temperature diffusion step there is forming of phosphorus glass (if POCl₃ is used for diffusion) or boron glass (if BCl₃ or BBr₃ are used for diffusion).

This glass can be removed using suitable chemical treatment.

The doped semiconductor layer 10 can be formed using other techniques, for example via sputtering, spin coating, PECVD deposit, PVD deposit, etc. in the presence of the dopants (e.g. in the form of phosphine PH3 or trimethylborate TMB).

Next, on the doped semiconductor layer 10 a doping layer 11 is formed of opposite electric type to the doped layer 10.

For example if the doped semiconductor layer 10 is of p+ type, the doping layer 11 is doped with boron.

If the doped semiconductor layer 10 is of n+ type, the doping layer 11 is doped with phosphorus.

The doping layer is preferably a layer of silicon nitride (of general formula SiNx).

It may also be a layer of silicon oxide (of general formula SiOx, e.g. SiO₂) or a transparent conductive oxide (such as ITO) or a stack of such layers.

This doping layer may optionally be deposited on a thin layer of silicon oxide (typically thinner than 10 nm, and in the order of 4 to 6 nm) which can be preserved and act as passivation layer for the structure. For example it may be a thermal or deposited oxide.

The doping layer 11 is advantageously formed by deposit e.g. of PECVD type, on the doped semiconductor layer 10, by adding to the deposit chamber a gas containing the desired doping element (for example phosphine PH3 to obtain phosphorus doping or TMB to obtain boron doping).

Other deposit techniques are of course possible.

For example, silicon oxide can be obtained by thermal growth (to form the passivation layer) and the heat treatment continued by injecting the desired dopant (e.g. phosphine) to obtain the doped oxide forming the doping layer.

Selective irradiation is then carried out i.e. limited to predefined regions on the back surface B of the substrate using a laser source.

The irradiation of a region of the doping layer has the effect of causing the doping atoms of said layer to diffuse into the underlying region of the doped semiconductor layer.

More specifically irradiation leads to fusion of the silicon in the semiconductor layer at the interface with the doping layer; the doping atoms therefore diffuse in this liquid phase and are electrically activated during recrystallization of the silicon.

In the remainder hereof the term “laser doping” will be use.

Three diffusion regimes have been evidenced as a function of the fluence of the laser source.

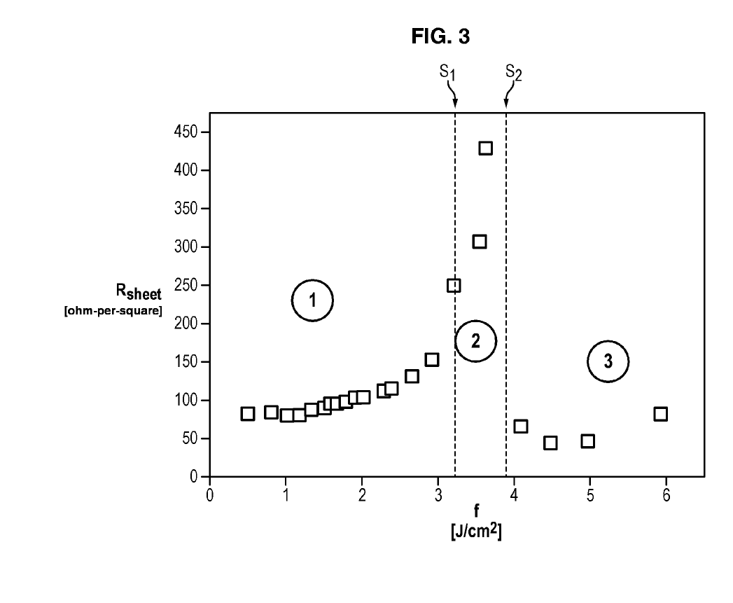

FIG. 3 illustrates the variation in Rsheet resistance (expressed in ohm-per-square) in a boron-doped layer 10 on which a doping layer 11 of SiN(P) has been deposited and irradiated by a laser source, as a function of the fluence f (expressed in J/cm²) of said source.

In this experiment, said p+ doped semiconductor layer 10 is formed by high temperature diffusion of BCl₃ at 940° C. for 30 minutes, producing an Rsheet resistance of 60 ohms-per-square, and it is then partly etched with a chemical solution for 10 minutes to adjust its Rsheet resistance so that it reaches 90 ohms-per-square.

This etching step is optional and can be omitted if the doped semiconductor layer directly derived from high temperature diffusion has the desired Rsheet resistance.

The doping layer 11 is deposited on this etched, doped semiconductor layer by PECVD at 300° C. with SiH₄, NH₃ and 50 sccm PH₃ precursor gases.

The laser source here is of excimer type, with a wavelength of 308 nm, pulse duration of 150 ns and frequency of 100 Hz.

At a first regime (region 1 in the graph) of between zero fluence and a first fluence threshold S1 which, for this source is 3 J/cm², the initial resistance of the doped layer 10 (p+ emitter) shows a slight increase from 90 to 150 ohms-per-square.

At a second regime (region 2) between the first threshold S1 and a second threshold S2, which for this source is 4 J/cm², a very strong increase in resistance is observed which reaches values higher than 450 ohms-per-square.

This strong increase translates compensation of the doped semiconductor layer 10, i.e. equilibrium concentration between electrically active boron and phosphorus atoms. A dopant is electrically active when it positions itself at a substitution site in the silicon crystal. It is not electrically active when it positions itself at an interstitial site. When dopant concentration is mentioned herein reference is made to the concentration of active dopants.

The initially p+ doped layer 10 is therefore converted to an electrically insulating layer, typically with an Rsheet resistance higher than 200 ohms-per-square.

The regime between the thresholds S1 and S2 can therefore be qualified as a “doping compensation range”.

Finally at a third regime (region 3) which corresponds to fluence higher than threshold S2, there is a strong decrease in resistance down to values lower than 50 ohms-per-square.

This decrease translates the fact that the phosphorus atoms in the doping layer 11 have massively diffused into the doped semiconductive layer 10, so that the concentration of boron atoms in the doped layer 10 becomes negligible (typically by a factor of at least 10 in terms of concentration) compared with the concentration of phosphorus atoms.

The initially p+ doped layer 10 is therefore converted to an n+ doped layer.

The second threshold S2 can then be qualified as a “doping inversion threshold”.

The doping levels identified in the three above-mentioned regimes are confirmed by analyses of the profiles of the P and B dopants in the doped layer measured by SIMS

### (Secondary Ion Mass Spectrometry)

The SIMS profiles give the total concentration of dopants (electrically active and inactive).

Nonetheless, since the majority of dopants are electrically active, the SIMS profile is a good indicator of inversed concentration.

These results were confirmed by ECV measurements (Electrochemical Capacitance Voltage), these measurements only giving the concentration of active dopants.

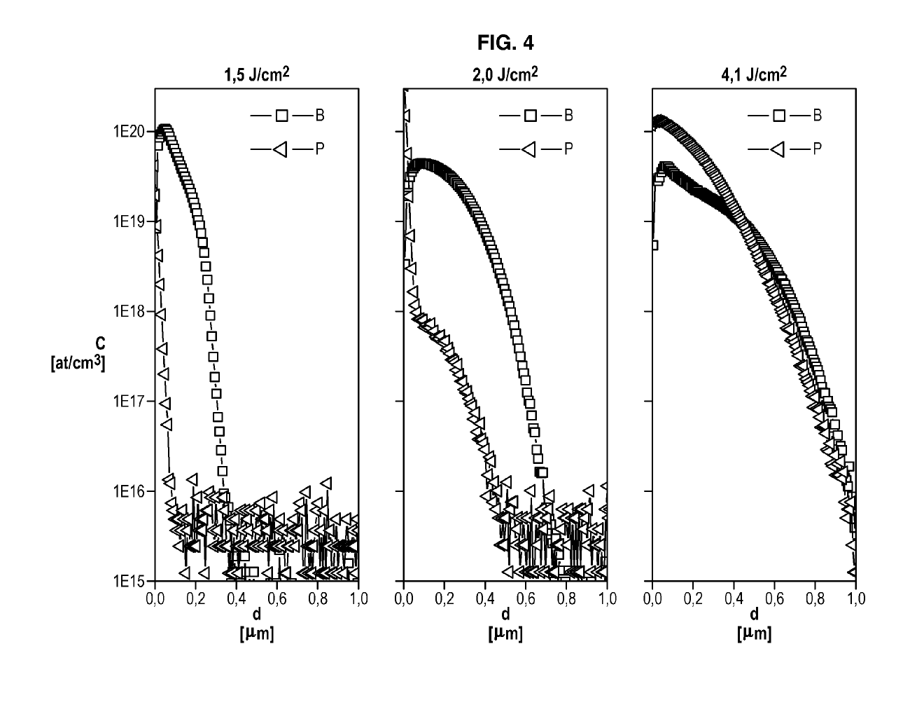

The graphs (a) to (c) in FIG. 4 show the profiles of boron and phosphorus (concentrations expressed in at/cm³) as a function of the depth d (expressed in μm) in the doped semiconductor layer 10 after irradiation of the doping layer 11 at respective fluence values of 1.5, 2.0 and 4.1 J/cm².

In graph (a), corresponding to a fluence of 1.5 J/cm², profile B exhibits a surface concentration of 1 E20 at/cm³ at a depth of 400 nm whilst profile P can be seen with a surface concentration of about 5E19 at/cm³ and a depth of 75 nm.

In graph (b), corresponding to a fluence of 2.0 J/cm², the initial profile of B has been modified with a surface concentration of 5E19 at/cm³ and depth of 700 nm. Profile P is more marked with a depth of 400 nm.

In graph (c), corresponding to a fluence of 4.1 J/cm², profile P is highly marked with a surface concentration of 1 E20 at/cm3 and depth of 1 μm whilst profile B shows a surface concentration of 3.5E19 at/cm³ and depth of 1 μm.

These curves therefore confirm the compensation mechanisms of the layer initially doped with boron, by laser diffusion of phosphorus from the doping layer of SiN(P).

Of course, the value of the fluence thresholds S1 and S2 is dependent upon the type of laser source.

This phenomenon can also be observed with other lasers of excimer type (typically in the wavelength range of 193 to 308 nm and with pulse durations of 15 to 300 ns).

This phenomenon was also observed with a Yag laser (355 nm, pulse duration 15 μs, 80 MHz)

In this case the power compensation threshold was evaluated at between 4.5 and 6.5 W (fluence being the power divided by spot size and pulse frequency).

The phenomenon of doping compensation and inversion was also observed when the doped semiconductor layer 10 is of n+ type and the doping layer 11 contains dopants of opposite electric type.

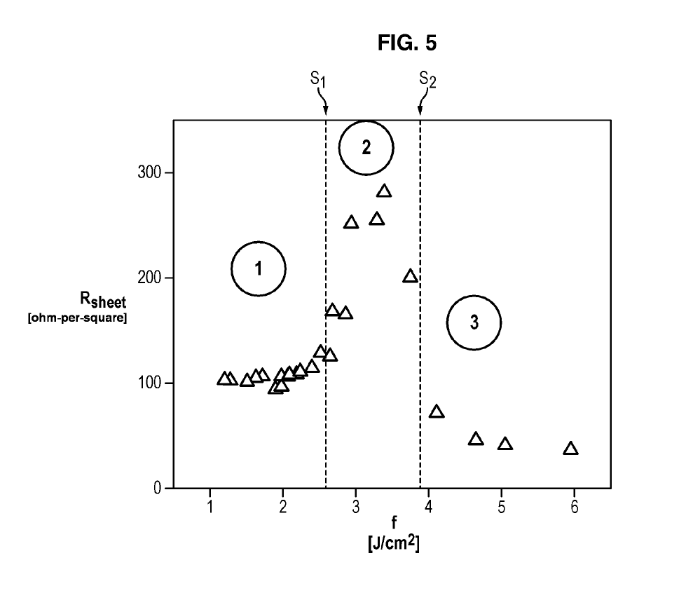

FIG. 5 therefore illustrates the variation in Rsheet resistance (expressed in ohms-per-square) in the phosphorus-doped semiconductor layer 10 on which a doping layer 11 of SiN(B) has been deposited and irradiated by a laser source, as a function of the fluence f (expressed in J/cm²) of said source.

Said n+ doped semiconductor layer 10 is formed by high temperature diffusion of POCl₃ at 830° C. for 30 minutes, then etched with a chemical solution for 10 minutes to obtain an Rsheet resistance of 100 ohms-per-square.

The doping layer 11 is deposited on this etched, doped semiconductor layer by PECVD at 300° C. with SiH₄, NH₃ and 50 sccm TMB precursor gases.

The laser source here is of excimer type with a wavelength of 308 nm, pulse duration of 150 ns and frequency of 100 Hz.

At the first regime (region 1 in the graph) between zero fluence and a first fluence threshold S1 which for this source is 2.6 J/cm², the initial resistance of the doped layer 10 (p+ emitter) increases slightly from 100 to 150 ohms-per-square.

At the second regime (region 2) or doping compensation range which lies between the first threshold S1 and a second threshold S2 which for this source is 3.9 J/cm², a very strong increase in resistance is observed which reaches values in the order of 300 ohms-per-square.

This strong increase translates compensation of the doped semiconductor layer 10 i.e. equilibrium concentration between boron and phosphorus atoms.

The initially n+ doped semiconductor layer 10 is therefore converted to an electrically insulating layer.

Finally at the third regime (region 3) called doping inversion regime which corresponds to fluence higher than the threshold S2, the resistance is strongly reduced reaching values lower than 50 ohms-per-square.

The initially n+ doped semiconductor layer 10 is therefore converted to a p+ doped layer.

The doping levels identified in the three above-mentioned regimes are confirmed by analyses of the profiles of the P and B dopants in the doped semiconductor layer as measured by SIMS (Secondary ion mass spectrometry).

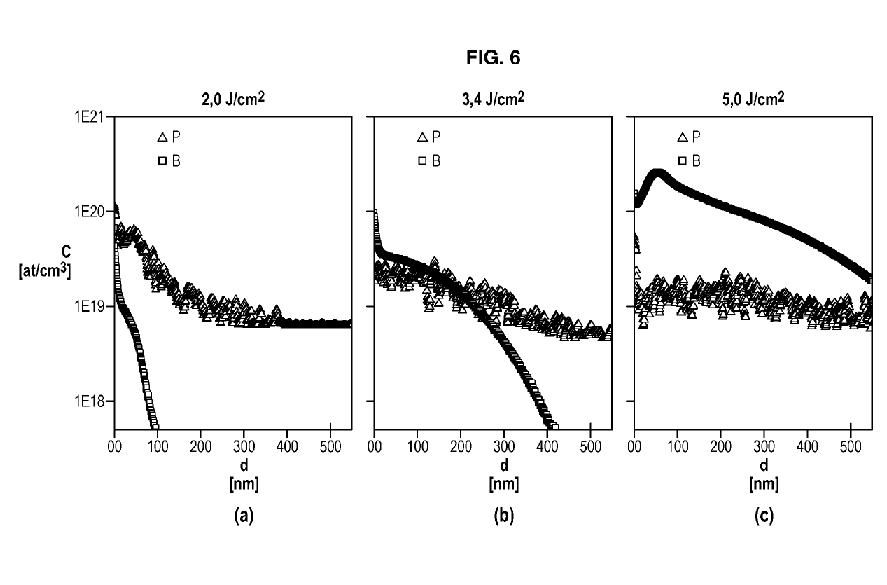

The graphs (a) to (c) in FIG. 6 show the profiles of boron and phosphorus (concentrations expressed in at/cm³) as a function of the depth d (expressed in nm) in the doped layer 10 after irradiation of the doping layer 11 at respective fluence values of 2.0, 3.4 and 5.0 J/cm².

In graph (a), corresponding to fluence of 2.0 J/cm², profile B shows a surface concentration of 1 E20 at/cm³ and depth of 100 nm whereas profile P can be seen with a surface concentration of about 1E19 at/cm³ and depth of 500 nm.

In graph (b), corresponding to a fluence of 3.4 J/cm², included in the doping compensation range, the initial profile of B has been modified with a surface concentration of 1^{E}20 at/cm³ and depth of 400 nm.

In graph (c), corresponding to fluence of 5.0 J/cm², i.e. higher than the doping inversion threshold, profile B is highly marked with a surface concentration of 1 E20 at/cm³ and depth of 500 nm whereas profile P shows a surface concentration of 1E19 at/cm³ and depth of 500 nm.

These curves therefore confirm the compensation mechanisms of the semiconductor layer initially doped with phosphorus by laser diffusion of boron from the doping layer of SiN(B).

In particularly advantageous manner, advantage is taken of the phenomenon of doping inversion evidenced above, to form regions in the doped semiconductor layer 10 which have doping of opposite type.

For this purpose a laser source is used having fluence higher than the doping inversion threshold S2, to irradiate regions 11a of the doping layer corresponding to the regions 10a of the doped semiconductor layer 10 for which it is desired to reverse the type of electric doping.

In FIG. 2A, this irradiation is schematized by the longest arrows.

Therefore in the first envisaged embodiment, if the doped semiconductor layer 10 is of p+ type, irradiation of regions 11a of the doping layer 11 SiN(P) with fluence higher than threshold S2 has the effect of forming n+ doped regions 10a in the doped semiconductor layer 10.

In the second envisaged embodiment, wherein the doped semiconductor layer 10 is of n+ type, irradiation of the doping layer 11 of SiN(B) with fluence higher than threshold S2 has the effect of forming p+ doped regions 10a in the doped semiconductor layer 10.

According to one preferred embodiment of the invention advantage is also taken of the phenomenon of doping compensation to form electrically insulating regions in the doped semiconductor layer 10, these regions allowing the n+ regions forming the repulsive electric field on the back surface to be insulated from the p+ regions forming the emitter.

For this purpose using a laser source having fluence in the doping compensation range [S1, S2], regions 11b of the doping layer are irradiated corresponding to regions 10b of the doped semiconductor layer 10 that it is desired to make electrically insulating.

In FIG. 2A, this irradiation is schematized by the shortest arrows.

As a variant, insulation can be obtained using other techniques e.g. laser ablation by local removal of the doped semiconductor layer 10.

In this case care must be taken so that laser ablation does not generate any thermal effect (which would cause doping by the doping layer).

For example a UV laser can be used with short pulse duration and low frequency e.g. laser at 355 nm, pulse duration of 15 μs and frequency of 200 KHz.

In the final photovoltaic cell a doped semiconductor layer 10 is therefore obtained in which there are three regions of different electric type.

In the first envisaged embodiment wherein the doped semiconductor layer 10 is initially p+ doped, the regions 10a of n+ type will therefore form the repulsive electric field of the back surface, whilst the regions 10c not affected by laser doping will form the p+ emitter, said regions 10a and 10c being separated by the electrically insulating regions 10b.

In the second envisaged embodiment, wherein the doped semiconductor layer 10 is initially n+ doped, the regions 10a of type p+ will therefore form the emitter whilst the regions 10c not affected by laser doping will form the repulsive electric field on the back surface, n+, said regions 10a and 10c being separated by the electrically insulating regions 10b.

The pattern of the different regions (n+, p+ and insulating) is typically that of an interdigitated comb i.e. repeat alternation of p+/insulating/n+/insulating strips.

For example the n+ regions have a width in the order of 300 μm, the electrically insulating regions have a width in the order of 100 μm, and the p+ regions have a width of between 600 and 1000 μm.

The width of irradiation is therefore adapted to the final type of the treated region.

One particular aspect of a cell produced by laser doping according to the invention is that all the p+, n+ and insulating regions on the back surface of the substrate all comprise a substantially homogeneous concentration of dopants of the first species.

Even if laser doping, depending on radiation fluence, has the effect of compensating or reversing the doping of some regions of the doped semiconductor layer 10, the dopants of the first species initially present in said layer are still contained therein.

The concentration of the first species of dopants may change slightly through diffusion at the time of laser irradiation; nevertheless a substantially homogeneous concentration of the first species of dopants is observed in the p+, n+ and insulating regions.

In a first variant, after the irradiation(s) the residual doping layer 11 is removed by chemical etching, irradiation possibly having locally removed all of part of the doping layer at the irradiated areas.

As is known per se a passivation layer 3, 6 is then formed on the front surface and back surface respectively of the substrate 1.

For example, the passivation layer may comprise a first layer of thermal SiO₂ having a thickness of between 5 and 20 nm, and a second layer of SiNx deposited by PECVD having a thickness between 50 and 150 nm.

Finally metal contacts 7 and 8 are screen printed on the p+ emitting regions (Ag paste) and on the n+ regions of the repulsive electric field (Ag/Al paste).

Annealing in an infrared oven allows contacting between the silicon of these regions with the metal of the contacts.

In a second variant, the doping layer may be a layer of SiNx deposited on a first thin layer of silicon oxide, e.g. of 6 nm. Optionally a second thin layer of silicon oxide can be provided on the SiNx layer for later optical confinement of the cell.

According to the invention doped regions of opposite type to the doped semiconductor layer are formed by adapted laser irradiation, the oxide layers present being sufficiently thin so as not to hinder the mechanism.

Insulating regions are also formed e.g. by laser irradiation of lower fluence.

It is therefore not necessary to remove the SiN doping layer which can be used in association with the underlying oxide layer as passivation layer.

It is then possible to form the metal contacts 7 and 8 directly e.g. by screen printing as previously.

As a variant, it is possible that at the irradiated regions the fluence is sufficiently high to lead also to the ablation of the surface SiO₂/SiN multilayer.

It can then be envisaged that, at these cavities, the contacts can be formed using other techniques e.g. electroplating.

For more information on this technique reference can be made to the article by Aleman et al, “Advances in Electroless Nickel Plating for the Metallization of Silicon Solar Cells using different Structuring Techniques for the ARC”, 24th European Photovoltaic Solar Energy Conference, 21-25 Sep. 2009, Hamburg.

It is optionally possible before this electroplating to open up contact tapping regions at the region having doping of opposite type to the irradiated region, e.g. by laser ablation.

In this case care is taken that laser ablation does not generate any thermal effect (which would lead to doping).

For this purpose a UV laser can be used for example, of short pulse duration and low frequency e.g. laser at 355 nm, of pulse duration 15 μs, and frequency of 200 KHz.

In this case, it will simultaneously be possible to form metallizations on the n+ and p+ regions by electroplating.

Example of Implementation of the Invention

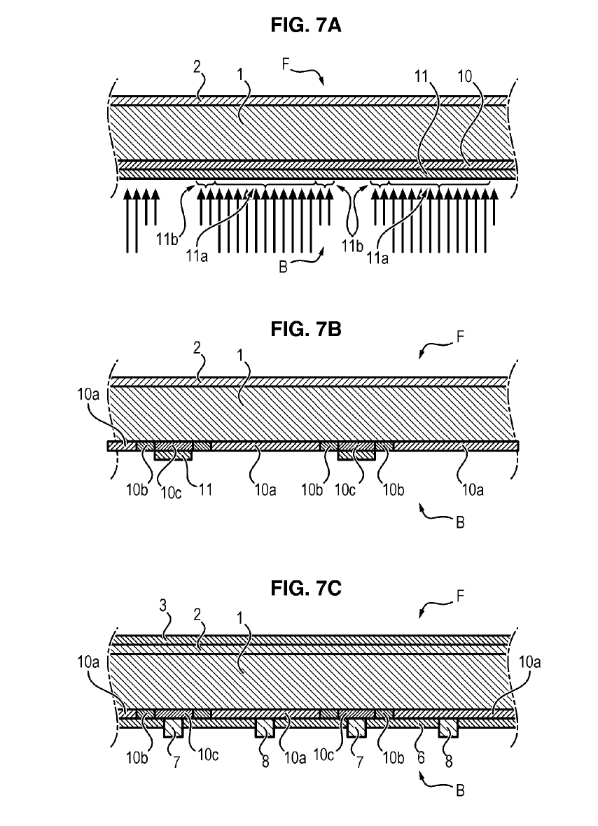

A detailed example of implementation of the invention is described with reference to FIGS. 7A to 7C.

At a first step (not illustrated) a substrate 1 of N doped silicon is prepared by removing the hardened region and polishing the two surfaces F and B of the substrate by chemical treatment of CP133 type for example, i.e. a mixture of HF, HNO₃ and CH₃COOH in proportions of 1:3:3.

A protective layer (not illustrated) is then deposited on the back surface B of the substrate 1.

The function of said layer is to protect the back surface B of the substrate during a subsequent texturizing step of the front surface F.

The protective layer may be formed for example of a 200 nm layer of silicon dioxide deposited by PECVD.

The back surface being protected, the front surface is texturized e.g. by chemical etching.

Typically, this etching is performed using 1% potassium hydroxide (KOH) for 40 minutes at 80° C.

This etching has the effect of imparting a non-planar surface to the front surface F, having raised reliefs e.g. of pyramidal type (not schematized here).

The protective layer is then removed from the back surface by selective attack using 2% hydrofluoric acid (HF).

With reference to FIG. 7A, high temperature diffusion of POCl₃ is then conducted at 830° C. for 30 minutes.

In this manner a layer 2 of n+ type on the front surface F of the substrate 1 (said layer 2 forming the repulsive field FSF) is simultaneously formed with an n+ doped semiconductor layer 10 on the back surface of the substrate.

Treatment with hydrofluoric acid allows the phosphorus glass to be removed that is formed during diffusion.

A 80 nm doping layer 11 of boron-doped SiN is deposited by PECVD.

To do so, at the time of depositing said layer, a flow of 50 sccm TMB is injected.

A first laser irradiation is then performed (schematized by the longest arrows) on the back surface B of the substrate 1 at a wavelength of 308 with pulses of 150 ns and fluence of 4.5 J/cm², localised to bands 11a of width 600 μm as per a comb pattern.

As can be seen in FIG. 6(c), this fluence is higher than the doping inversion threshold.

Therefore the boron atoms of the irradiated bands 11a of the doping layer 11 diffuse into the underlying bands 10a of the doped semiconductor layer 10 so as to exceed the concentration of the phosphorus atoms.

As illustrated in FIG. 7B, emitter regions of p++ type are thereby formed in the bands 10a of the doped layer 10.

Laser irradiation (schematized by the shortest arrows) is also performed on the back surface B of the substrate 1 at a wavelength of 308 nm with pulses of 150 ns and fluence of 3.2 J/cm², localised to bands 11b of 100 μm width adjacent to the bands 10a of p++ type formed previously.

As can be seen in FIG. 6(b), this fluence lies within the doping compensation range.

As a result, the boron atoms in the irradiated bands 11b of the doping layer 11 diffuse into the underlying bands 10b of the doped semiconductor layer 10 so as to obtain equilibrium concentration of boron and phosphorus atoms in said bands 10b.

As illustrated in FIG. 7B, in the bands 10b of the doped layer 10 there are thus formed electrically insulating regions which insulate the p++ emitter regions 10a from the remaining BSF regions 10c of n+ type.

Those portions of the doping layer 11 which have not been irradiated are then removed via chemical process.

With reference to FIG. 7C, thermal oxidation of the substrate is then carried out in an oxygen atmosphere at 950° C. for 30 minutes, to form a 10 nm oxide layer.

A 60 nm layer of SiNx is deposited by PECVD on the front surface F and of 100 nm on the back surface B to obtain respective passivation layers 3 and 6.

A silver paste of width 100 μm is then screen printed in a comb pattern centred on the BSF regions 10c, to form contacts 7.

Additionally in a comb pattern centred on the emitting regions 10a, a silver/aluminium paste of width 300 μm is screen printed to form contacts 8.

Finally the contacts are annealed in a furnace at 890° C.

This example is evidently given solely for illustrative purposes and the scope of the invention is not limited to this particular embodiment.

1. A method for producing a photovoltaic cell with interdigitated back contacts, comprising:
providing a doped silicon substrate;
forming on the back surface of said substrate, a semiconductor layer doped with a first species of dopants;
forming, on said doped semiconductor layer, a so-called doping layer comprising a second species of dopants of opposite electric type to the first species;
forming in the doped semiconductor layer, at least one doped region of opposite type to the first species via selective irradiation of at least one region of the doping layer using a luminous flux whose fluence is higher than a threshold, called “doping inversion threshold”, beyond which the dopants of the irradiated region of the doping layer diffuse into the region underlying the doped semiconductor layer so as to exceed the concentration of the first dopant species;
forming in the doped semiconductor layer at least one electrically insulating region via selective irradiation of at least one region of the doping layer using luminous flux having fluence within a range called “doping compensation range”, that is lower than said doping inversion threshold and at which the dopants of the irradiated region of the doping layer diffuse into the region underlying the doped semiconductor layer to obtain equilibrium concentration of the two species of dopants in said region.

2. The method according to claim 1, wherein said selective irradiation is performed via the back surface of the substrate.

3. The method of claim 1, wherein the doped layer is formed by high temperature diffusion of a reagent containing the first dopant species via the back surface of the substrate.

4. The method of claim 1, wherein the doping layer is a layer of silicon nitride doped with the second dopant species deposited by plasma enhanced chemical vapour deposit (PECVD).

5. The method of claim 1, wherein the first dopant species is of same electric type as the substrate.

6. The method of claim 5, wherein the substrate is n doped and the first dopant species is phosphorus.

7. The method of claim 6, wherein the doped semiconductor layer is formed by high temperature diffusion of POCl₃ via the back surface of the substrate.

8. The method of claim 5, wherein the doping layer is a layer of boron-doped silicon nitride.

9. The method of claim 1, wherein the first dopant species is of opposite electric type to the substrate.

10. The method of claim 9, wherein the substrate is n doped and the first dopant species is boron.

11. The method of claim 10, wherein the doped semiconductor layer is formed by high temperature diffusion of BBr₃ or BCl₃ via the back surface of the substrate.

12. The method of claim 9, wherein the doping layer is a layer of phosphorus-doped silicon nitride.

13. The method or claim 1, wherein the thickness of the doped semiconductor layer is between 100 nm and 1 μm, and in that the thickness of the doping layer is between 10 and 300 nm.

14. The method of claim 1, wherein before forming the doping layer, a layer of silicon oxide is formed on the doped semiconductor layer.

15. The method of claim 1, wherein the selective irradiations are performed by laser.

16. The method of claim 1, further comprising, on the front surface of said substrate, forming doped semiconductor layer of same electric type as the substrate, so as to form a repulsive electric field on said front surface.

17. The of claim 16, wherein said layer of repulsive electric field is formed by high temperature diffusion of POCl₃ in the substrate.

18. A structure comprising a doped silicon substrate successively coated with a semiconductor layer doped with a first dopant species and a so-called doping layer comprising a second dopant species of opposite electric type to the first species, wherein the doped semiconductor layer comprises at least one doped region of opposite type to the first species, comprising dopants of the second species in a concentration higher than the concentration of the first dopant species, and an electrically insulating region comprising dopants of the second species in equilibrium concentration with the concentration of dopants of the first species.

19. A photovoltaic cell with interdigitated back contacts comprising a doped silicon substrate and, on the back surface of said substrate, alternating p+ doped regions and n+ doped regions in the form of an interdigitated comb, wherein all said p+ and n+ regions have a substantially homogeneous concentration of dopants of one same species, and said cell further comprising, on the back surface of the substrate, a plurality of electrically insulating regions separating the p+ doped regions and n+ doped regions, said electrically insulating regions having a concentration of dopants of said species that is substantially homogeneous with that of the p+ regions and n+ doped regions.
